(19) United States
(12) Patent Application Publication
(10) Pub. No.: US 2007/0197040 A1
(43) Pub. Date: Aug. 23, 2007

(54) PLASMA ETCHING METHOD, PLASMA ETCHING APPARATUS, CONTROL PROGRAM AND COMPUTER-READABLE STORAGE MEDIUM

(75) Inventors: Akinori Kitamura, Nirasaki-shi (JP); Masanobu Honda, Nirasaki-shi (JP); Nozomi Hirai, Nirasaki-shi (JP); Kumiko Yamazaki, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/677,736

(22) Filed: Feb. 22, 2007

Related U.S. Application Data
(60) Provisional application No. 60/776,949, filed on Feb. 28, 2006.

(30) Foreign Application Priority Data
Feb. 23, 2006 (JP) 2006-047113
Dec. 11, 2006 (JP) 2006-333159

(51) Int. Cl. H01L 21/461; H01L 21/302; C23F 1/00

(52) U.S. Cl. 438/710; 438/706; 438/718; 438/729; 156/345.35

(57) ABSTRACT

A plasma etching method includes the step of performing a plasma etching on a silicon-containing dielectric layer formed on a substrate to be processed by using a plasma, while using an organic layer as a mask. The plasma is generated from a processing gas at least including a C₆F₆ gas, a rare gas and an oxygen gas, and a flow rate ratio of the oxygen gas to the C₆F₆ gas (an oxygen gas flow rate/a C₆F₆ gas flow rate) is set to be about 2.8 to 3.3.

### FIELD OF THE INVENTION

The present invention relates to a plasma etching method for etching a silicon-containing dielectric layer formed on a substrate to be processed by using an organic layer as a mask; and also relates to a plasma etching apparatus, a control program to be used therefor, and a computer-readable storage medium storing the control program therein.

### BACKGROUND OF THE INVENTION

In a manufacturing process of semiconductor devices, a plasma etching is performed on a silicon-containing dielectric layer (for instance, a SiO₂ film, a SiOC film, or the like) by using an organic layer such as a photoresist as a mask, to thereby form, for example, contact holes. In general, a gaseous mixture of, for example, C₄F₆/Ar/O₂ is employed as a processing gas for plasma generation in the plasma etching.

Further, there is known a technique for improving a selectivity of SiO₂ against a polycrystalline silicon by using a gaseous mixture of a C₆F₆ gas/a freon gas or an oxygen gas/a He gas or an argon gas as a processing gas when performing a plasma etching (see, e.g., Patent Reference 1).

Moreover, there is also known a technique for improving a selectivity of SiO₂ against a Si₃N₄ layer by using a processing gas made up of C₆F₆ for the plasma etching of the SiO₂ (see, e.g., Patent Reference 2).

Further, there has been proposed using a processing gas containing a fluorocarbon gas at least having four carbon atoms with a F/C ratio smaller than 2; an argon or xenon gas; and an oxygen gas to perform a plasma etching of SiO₂ selectively against a photoresist, wherein a flow rate ratio between the oxygen gas and the fluorocarbon gas is set to range from 0.4:1 to 2:1, and a C₆F₆ gas is employed as the fluorocarbon gas (see, e.g., Patent Reference 3)

[Patent Reference 1]

Japanese Patent Laid-open Application No. S57-155732

[Patent Reference 2]

Japanese Patent Laid-open Application No. H6-275568

[Patent Reference 3]

### Japanese Patent Laid-open Application No. 2004-512668

When forming contact holes of high aspect ratios by using an organic layer such as a photoresist as a mask, a high selectivity of a target layer to be etched against the mask is required. The necessity to meet such a requirement is getting stronger to achieve a thickness reduction of a mask layer, while improving productivity. In the conventional techniques as described above, however, the selectivity is typically about 5 and about 10 at the highest Thus, a plasma etching method capable of performing a plasma etching with a high selectivity is required to be developed.

### SUMMARY OF THE INVENTION

It is, therefore, an object of the present invention to provide a plasma etching method capable of improving a selectivity of a silicon-containing dielectric layer against an organic layer employed as a mask; and also to provide a plasma etching apparatus, a control program to be used therefor, and a computer-readable storage medium storing the control program therein.

In accordance with a first aspect of the present invention, there is provided a plasma etching method including the step of:

performing a plasma etching on a silicon-containing dielectric layer formed on a substrate to be processed by using a plasma, while using an organic layer as a mask,

wherein the plasma is generated from a processing gas at least including a C₆F₆ gas, a rare gas and an oxygen gas, and a flow rate ratio of the oxygen gas to the C₆F₆ gas (an oxygen gas flow rate/a C₆F₆ gas flow rate) is set to be about 2.8 to 3.3.

It is preferable that the organic layer is a photoresist layer, and the silicon-containing dielectric layer is a silicon oxide layer.

It is preferable that the rare gas is an argon gas.

It is preferable that the processing gas further includes an additional gas made up of a fluorocarbon gas having a fluorine/carbon (F/C) atom ratio equal to or larger than 2.

It is preferable that the additional gas is CF₄, C₂F₆, C₃F₈, C₄F₈, C₅F₁₂, or C₆F₁₄.

It is preferable that the plasma etching is performed, in a processing chamber having a lower electrode for mounting the substrate to be processed thereon and an upper electrode disposed to face the lower electrode, by applying high frequency powers between the upper and the lower electrode.

It is preferable that the high frequency powers include a first high frequency power applied to the upper electrode; and a second high frequency power applied to the lower electrode, wherein a frequency of the second high frequency power is lower than that of the first high frequency power.

In accordance with a second aspect of the present invention, there is provided a plasma etching apparatus comprising:

a processing chamber for accommodating therein a substrate to be processed;

a processing gas supply unit for supplying a processing gas into the processing chamber;

a plasma generating unit for converting the processing gas supplied from the processing gas supply unit into a plasma, thereby plasma-etching the substrate; and

a control unit for performing the plasma etching method of the first aspect in the processing chamber.

In accordance with a third aspect of the present invention, there is provided a computer-executable control program, which controls, when executed, a plasma etching apparatus to perform the plasma etching method of the first aspect.

In accordance with a fourth aspect of the present invention, there is provided a computer-readable storage medium for storing therein a computer executable control program, wherein the control program, when executed, controls a plasma etching apparatus to perform the plasma etching method of the first aspect.

In accordance with the present invention, there is provided a plasma etching method for improving a selectivity of a silicon-containing dielectric layer against an organic photoresist layer in comparison with conventional cases; and there are also provided a plasma etching apparatus, a control program to be used therefor, and a computer-readable storage medium storing the control program therein.

### BRIEF DESCRIPTION OF THE DRAWINGS

The above and other objects and features of the present invention will become apparent from the following description of embodiments given in conjunction with the accompanying drawings, in which:

FIGS. 1A and 1B provide cross sectional views of a semiconductor wafer to which a plasma etching method in accordance with an embodiment of the present invention is applied;

FIG. 2 sets forth a schematic configuration view of a plasma etching apparatus in accordance with the embodiment of the present invention; and

FIG. 3 presents a diagram to explain definitions of an etching rate and a selectivity at a flat portion and a shoulder portion.

### DETAILED DESCRIPTION OF THE EMBODIMENTS

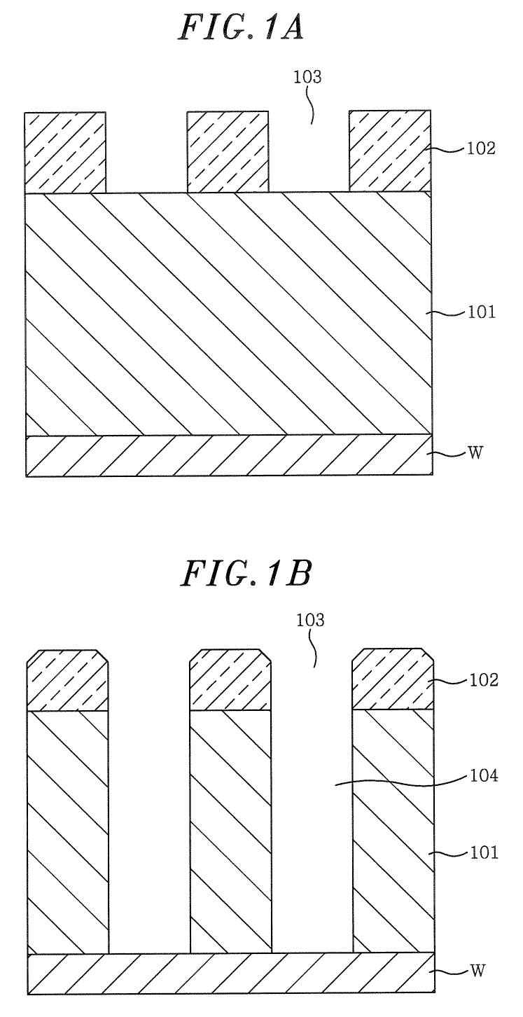

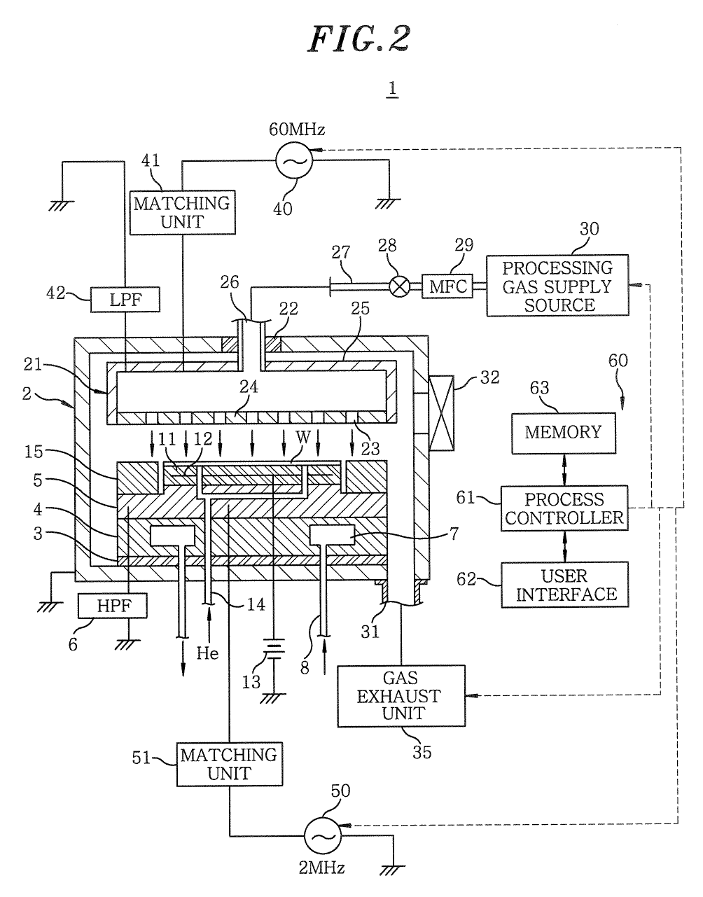

Hereinafter, an embodiment of the present invention will be described in detail with reference to the accompanying drawings. FIGS. 1A and 1B are enlarged cross sectional configuration views of a semiconductor wafer W which is used as a target object to be etched in a plasma etching method in accordance with an embodiment of the present invention. FIG. 2 illustrates a cross sectional configuration of a plasma etching apparatus 1 in accordance with the embodiment of the present invention. Below, a configuration of the plasma etching apparatus 1 will be first explained with reference to FIG. 2.

A plasma etching apparatus 1 is configured as a capacitively coupled parallel plate type etching apparatus having an upper and a lower electrode plate placed to face each other in parallel and respectively connected to power supplies for plasma generation.

The plasma etching apparatus 1 has a cylindrical processing chamber (processing vessel) 2 formed of, for example, aluminum whose surface is anodically oxidized, and the chamber 2 is grounded. A substantially columnar susceptor support 4 for mounting thereon a target object to be processed, e.g., a semiconductor wafer W is installed at a bottom portion of the processing chamber 2 via an insulating plate 3 such as ceramic. Further, a susceptor 5 serving as a lower electrode is mounted on the susceptor support 4, and the susceptor 5 is connected to a high pass filter (HPF) 6.

A coolant path 7 is formed inside the susceptor support 4, and a coolant is introduced into the coolant path 7 via a coolant introducing line 8. By the circulation of the coolant through the coolant path 7, the cold heat of the coolant is transferred from the susceptor 5 to the semiconductor wafer W, whereby the processing surface of the wafer W is maintained at a desired temperature level.

The susceptor 5 has an upper central portion of a disk shape, which protrudes higher than its peripheral portion, and an electrostatic chuck 11 that is shaped substantially identical to the semiconductor wafer W is disposed on the upper central portion of the susceptor 5. The electrostatic chuck 11 includes an electrode 12 embedded in an insulating member. The semiconductor wafer W is electrostatically attracted to the electrostatic chuck 11 by, for example, a Coulomb force generated by applying a DC voltage of, for example, 1.5 kV to the electrode 12 from a DC power supply 13 connected thereto.

Further, formed through the insulating plate 3, the susceptor support 4, the susceptor 5 and the electrostatic chuck 11 is a gas channel 14 for supplying a heat transfer medium (e.g., a He gas), to the rear surface of the semiconductor wafer W. Thus, the cold heat of the susceptor 5 is transferred from the susceptor 5 to the semiconductor wafer W through the heat transfer medium, so that the wafer W is maintained at a specific temperature level.

An annular focus ring 15 is disposed on the periphery of the top surface of the susceptor 5 to surround the semiconductor wafer W loaded on the electrostatic chuck 11. The focus ring 15 is formed of a conductive material such as silicon and serves to improve uniformity of etching.

An upper electrode 21 is disposed above the susceptor 5, while facing it in parallel. The upper electrode 21 is supported at an upper portion of the processing chamber 2 via an insulating member 22. The upper electrode 21 includes an electrode plate 24; and an electrode support 25 that serves to support the electrode 24 and is made up of a conductive material. The electrode plate 24 is configured to face the susceptor 5 and is provided with a number of injection openings 23. The electrode plate 24 is formed of, for example, silicon or aluminum whose surface is anodically oxidized (alumite treated) with a quartz cover attached thereto. A distance between the susceptor 5 and the upper electrode 21 is adjustable.

A gas inlet port 26 is formed at a center of the electrode support 25 of the upper electrode 21, and a gas supply line 27 is coupled to a gas inlet port 26. Further, the gas supply line 27 is connected to a processing gas supply source 30 via a valve 28 and a mass flow controller 29.

A gas exhaust line 31 is connected to a bottom portion of the chamber 2 and coupled to a gas exhaust unit 35. The gas exhaust unit 35 includes a vacuum pump such as a turbo molecular pump, and serves to create a depressurized atmosphere in the processing chamber 2, i.e., to evacuate the chamber 2 such that the inner pressure thereof is reduced down to a specific vacuum level, e.g., 1 Pa or less. Further, a gate valve 32 is installed at a sidewall of the processing chamber 2. The wafer W is transferred between the processing chamber 2 and an adjacent load lock chamber (not shown) while the gate valve 32 is opened.

A first high frequency power supply 40 is connected to the upper electrode 21 via a matching unit 41. Further, a low pass filter (LPF) 42 is connected to the upper electrode 21. The first high frequency power supply 40 is of a frequency ranging from about 50 to 150 MHz. By applying a high frequency power in such a frequency range, a high-density plasma in a desirable dissociated state can be generated in the processing chamber 2.

Further, a second high frequency power supply 50 is connected to the susceptor 5 serving as the lower electrode via a matching unit 51. The second high frequency power supply 50 has a frequency range lower than that of the first high frequency power supply 40. By applying a power of a frequency in such a range, a proper ionic action can be facilitated without causing any damage on the wafer W, which is an object to be processed. Preferably, the frequency of the second high frequency power supply 50 is determined within a range from about 1 to 20 MHz.

The whole operation of the plasma etching apparatus 1 having the above-described configuration is controlled by a control unit 60. The control unit 60 includes a process controller 61 having a CPU for controlling each component of the plasma etching apparatus 1; a user interface 62; and a memory 63.

The user interface 62 includes a keyboard for a process manager to input a command to operate the plasma etching apparatus 1; a display for showing an operational status of the plasma etching apparatus 1; and the like.

Moreover, the memory 63 stores therein, e.g., control programs (software) and recipes including processing condition data and the like to be used in realizing various processes, which are performed in the plasma etching apparatus 1 under the control of the process controller 61. When a command is received from the user interface 62, the process controller 61 retrieves a necessary recipe from the memory 63 as required to execute the command to perform a desired process in the plasma etching apparatus 1 under the control of the process controller 61. The necessary recipe can be retrieved from a computer-readable storage medium (e.g., a hard disk, a CD-ROM, a flexible disk, a semiconductor memory, or the like), or can be transmitted from another apparatus via, e.g., a dedicated line, if necessary.

Hereinafter, a plasma etching method for selectively etching a silicon-containing dielectric layer (e.g., a SiO₂ layer, a SiOC layer, or the like) by using an organic layer (e.g., photoresist) as a mask will be explained, wherein the plasma etching method is performed by the plasma etching apparatus 1 configured as described above. First, the gate valve 32 is opened, and then the semiconductor wafer W is loaded into the processing chamber 2 via the load lock chamber (not shown) and mounted on the electrostatic chuck 11. Then, a DC voltage is applied to the electrode 12 from the DC power supply 13, whereby the semiconductor wafer W is electrostatically attracted to the electrostatic chuck 11. Subsequently, the gate valve 32 is closed, and then the processing chamber 2 is evacuated to a specific vacuum level by the gas exhaust unit 35.

Thereafter, the valve 28 is opened, and a processing gas (etching gas) is supplied into a hollow space of the upper electrode 21 via the gas supply line 27 and the gas inlet port 26 from the processing gas supply source 30 while its flow rate is controlled by the mass flow controller 29. Then, the processing gas is discharged uniformly toward the semiconductor wafer W through the injection openings 23 of the electrode plate 24, as indicated by arrows in FIG. 2.

Then, the internal pressure of the processing chamber 2 is maintained at a specific pressure level, and a high frequency power of a predetermined frequency is applied to the upper electrode 21 from the first high frequency power supply 40, whereby a high frequency electric field is generated between the upper electrode 21 and the susceptor 5 serving as the lower electrode. As a result, the processing gas is dissociated and converted into a plasma.

Meanwhile, a high frequency power of a frequency lower than that from the first high frequency power supply 40 is applied to the susceptor 5 serving as the lower electrode from the second high frequency power supply 50. As a result, ions among the plasma are attracted toward the susceptor 5, so that etching anisotropy is improved by ion assist.

Then, upon the completion of the plasma etching, the supply of the high frequency powers and the processing gas is stopped, and the semiconductor wafer W is retreated out of the processing chamber 2 in the reverse sequence as described above.

Below, the plasma etching method in accordance with the embodiment of the present invention will be described with reference to FIGS. 1A and 1B. As shown in FIG. 1A, on the surface of a semiconductor wafer W, which is a substrate to be processed, there is formed a SiO₂ layer 101 of a specific thickness (e.g., 2000 nm) to be used as a silicon-containing dielectric layer, and on the SiO₂ layer 101, there is formed a photoresist layer (e.g., a KrF resist, an ArF resist, an X-ray resist, or the like) 102 of a certain thickness (e.g., 660 nm) to be used as an organic layer. A preset pattern is transferred to the photoresist layer 102 by an exposure and developing process, whereby the photoresist layer 102 is formed as a mask having openings 103 of the preset pattern (e.g., a number of circular holes having diameters of 0.15 μm). The semiconductor wafer W in the state shown in FIG. 1A is loaded into the processing chamber 2 of the plasma etching apparatus 1.

In the processing chamber 2, the SiO₂ layer 101 is plasma etched selectively against the photoresist layer 102 by using the photoresist layer 102 as a mask, whereby holes 104 such as contact holes are formed as shown in FIG. 1B. This plasma etching is performed by a plasma generated from a processing gas at least containing a C₆F₆ gas, a rare gas and an oxygen gas, wherein a flow rate ratio of the oxygen gas to the C₆F₆ gas (a flow rate of the oxygen gas/a flow rate of the C₆F₆) is set to be about 2.8 to 3.3.

As the rare gas, Ne, Ar, Kr, Xe, or the like can be employed, for example, and particularly, Ar can be appropriately utilized. Further, if necessary, another gas, for instance, another fluorocarbon gas (e.g., a saturated aliphatic compound such as a fluorocarbon gas having a fluorine/carbon (F/C) atom ratio equal to or larger than 2, e.g., CF₄, C₂F₆, C₃F₈, C₄F₈, C₅F₁₂, C₆F₁₄, or the like) can be added to the processing gas.

In a first test example, the above-explained plasma etching process was performed on a semiconductor wafer W having a configuration as shown in FIG. 1 (photoresist layer=660 nm, SiO₂ layer=2000 nm) by using the plasma etching apparatus 1 shown in FIG. 2 according to a processing recipe to be specified below, whereby holes 104 having diameters of 0.15 μm were formed.

The processing recipe for the test example is retrieved from the memory 63 of the control unit 60 and executed by the process controller 61. The process controller 61 controls each components of the plasma etching apparatus 1 based on a control program, whereby an etching process is performed according to the retrieved recipe as follows:
etching gas: C₆F₆/Ar/O₂=20/300/63 sccm;
pressure: 2.0 Pa (15 mTorr);
power (upper electrode/lower electrode): 2200 W (60 MHz)/1800 W (2 MHZ);
distance between the upper and the lower electrode: 25 mm;
temperature (upper electrode/chamber sidewall/lower electrode): 60° C./50° C./−10° C.;
He pressure: 665/3325 Pa (5/25 Torr);
etching time: 180 seconds.

In the above plasma etching, an etching rate of the SiO₂ layer at a hole portion was 551 nm/min. Further, a selectivity of the SiO₂ layer against the photoresist (an etching rate of the SiO₂ layer/an etching rate of the photoresist) was 35.2 at a flat portion and 17.0 at a shoulder portion.

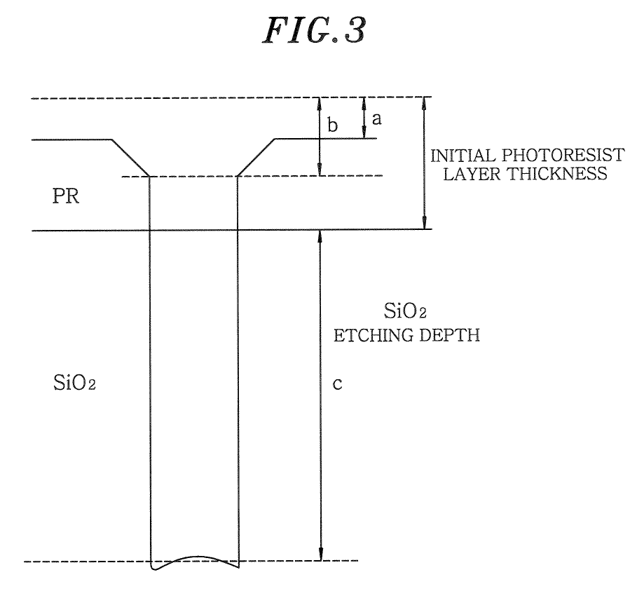

Here, the etching rate of the SiO₂ layer represents a value obtained by dividing an etching depth c of an etched hole by an etching time, as shown in FIG. 3. Further, the selectivity at the flat portion refers to a ratio c/a between the etching depth c and a thickness decrement a at a flat portion of the photoresist PR with respect to an initial photoresist layer thickness, as shown in FIG. 3. The shoulder portion is an obliquely etched portion (facet portion) formed at the mouth of an opening of the photoresist, as shown in FIG. 3, and the selectivity at the shoulder portion refers to a ratio c/b between the etching depth c and a thickness decrement b at the shoulder portion of the photoresist PR with respect to the initial photoresist layer thickness.

In a comparative example, a plasma etching was performed under the same processing conditions as those for the first test example excepting that an etching gas was changed to C₄F₆/Ar/O₂ whose flow rates were set to be 20/300/17 sccm. As a result of the comparative example, an etching rate of a SiO₂ layer at a hole portion was 558 nm/min, and a selectivity of the SiO₂ layer against a photoresist was 9.7 at a flat portion and 5.7 at a shoulder portion.

As revealed from the above results, the substantially same level of etching rate could be obtained in the first test example and the comparative example; and in the first test example, the selectivity of the SiO₂ layer against the photoresist could be improved up to about three times as great as that of the comparative example at both of the shoulder and the flat portion. Further, in the first test and the comparative examples, substantially identical etch profile (capability to form deep holes without suffering an etch stop) were obtained in forming holes having diameters of 0.15 μm.

Further, in the first test example, an etching was performed on the same target object under the same processing conditions, while varying the flow rate of the oxygen gas among the processing gas. The results are shown in Table 1.

TABLE 1

| Oxygen gas flow | Etching | Selectivity | |
|---|---|---|---|
| rate | rate | (shoulder | |
| (sccm) | (nm/min) | portion) | Etch profile |
| 55 | 262 | — | Etch stop occurred |
| 60 | 526 | 41.6 | Etch stop not |
| | | | occurred |
| 62 | 543 | 19.9 | Etch stop not |
| | | | occurred |
| 63 | 551 | 17.0 | Etch stop not |
| | | | occurred |
| 65 | 523 | 12.4 | Etch stop not |
| | | | occurred |
| 66 | 523 | 5.5 | Etch stop not |
| | | | occurred |
| 68 | 505 | 4.2 | Etch stop not |
| | | | occurred |

As shown in Table 1, since deposits tend to increase if the oxygen gas rate is reduced, the etch profile deteriorates. For example, if the oxygen gas rate is 55 sccm, an etch stop occurs, causing a failure to form a hole.

Meanwhile, if the oxygen gas rate is increased, the selectivity of the SiO₂ layer against the photoresist tends to be reduced. For example, if the oxygen gas rate is over 66 sccm, e.g., 68 sccm, the selectivity of the SiO₂ layer against the photoresist at the shoulder portion drops to 4.2.

Further, the above-described plasma etching process was performed for the cases where the oxygen gas flow rate falls within a range from 55 sccm to 60 sccm, specifically, for the cases where the oxygen gas flow rate was 56 sccm, 57 sccm, and 59 sccm, respectively. With the oxygen gas flow rates in such a range, it was possible to form holes sufficiently without suffering an etch stop.

Accordingly, a fine etching profile and a high selectivity of a SiO₂ layer against a photoresist could be both obtained when the oxygen gas flow rate was in a range from 56 to 66 sccm, that is, when a ratio of the oxygen gas flow rate to a C₄F₆ flow rate (20 sccm) was in a range from 2.8 to 3.3. In such a case, the range of the oxygen gas flow rate available was as wide as 10 sccm (56 to 66 sccm), and the oxygen gas flow rate could be appropriately changed as required. In contrast, when a gaseous mixture of C₄F₆/Ar/O₂ was used as an etching gas, an oxygen gas flow rate range in which a sufficient selectivity of the SiO₂ layer against the photoresist could be obtained without causing an etch stop was found to be as narrow as 3 sccm.

In the following, there is described a second test example in which a fluorocarbon gas having a F/C ratio equal to or larger than a value of 2 (e.g., CF₄, C₂F₆, C₃F₈, C₄F₈, C₅F₁₂, or C₆F₁₄) was added to the processing gas employed in the first test example as an additional gas. The additional gas is a fluorine-rich gas. In general, since the additional gas serves to increase the etching rate of the photoresist as well as the etching rate of the SiO₂ layer, the selectivity of the SiO₂ layer against the photoresist is reduced. Since, however, a high selectivity of the SiO₂ layer against the photoresist can be obtained in the plasma etching method in accordance with the embodiment of the present invention, the reduction of the SiO₂ selectivity due to the addition of the additional gas can be compensated, so that a high etching rate of the SiO₂ layer can be still obtained.

In the second test example, a plasma etching was performed for each of the cases of adding CF₄, C₄F₈ and C₅F₁₂, C₆F₁₄ as additional gases under the following processing conditions:
etching gas: C₆F₆/additional gas/Ar/O₂=20/10/300/63 sccm;
pressure: 2.0 Pa (15 mTorr);
power (upper electrode/lower electrode): 2200 W (60 MHz)/1800 W (2 MHz);
distance between the upper and the lower electrode: 25 mm;
temperature (upper electrode/chamber sidewall/lower electrode): 60/50/−10° C.;
He pressure: 665/3325 Pa (5/25 Torr);
etching time: 90 seconds.

Table 2 shows an etching rate of a SiO₂ layer at a hole portion and a selectivity of the SiO₂ layer against a photoresist (the etching rate of the SiO₂ layer/an etching rate of the photoresist) at a flat portion for each of the cases of using the different additional gases. For comparison, Table 2 also shows a measurement result of an etching rate obtained by performing a plasma etching under the same processing conditions as above excepting that no additional gas is used therein.

TABLE 2

| | Etching rate | Selectivity |
|---|---|---|
| Additional gas | (nm/min) | (flat portion) |
| None | 587 | — |
| CF₄ | 642 | 20.5 |
| C₄F₈ | 701 | 526 |
| C₅F₁₂ | 698 | 20.1 |
| C₆F₁₄ | 795 | 11.5 |

As shown in Table 2, the etching rates of the SiO₂ layers could be improved by using the additional gases, and required levels of selectivities (no smaller than 11.5) could be obtained. Then, a hole of a preset depth was formed by performing a 25% of overetching with an initial photoresist thickness of 388 nm under the same processing conditions as specified in the second test example except the etching time, and a residual thickness of the photoresist and an etching time were measured for each of cases of using no additional gas and using CF₄, C₄F₈, and C₆F₁₄ as additional gases, respectively. The results are provided in Table 3.

TABLE 3

| | Residual thickness of | |
|---|---|---|
| | the photoresist | Etching time |
| Additional gas | (nm) | (flat portion) |
| none | 370 | 196 |
| CF₄ | 291 | 181 |
| C₄F₈ | 336 | 166 |
| C₆F₁₄ | 227 | 146 |

As shown in Table 3, by using the additional gases, etching times could be shortened in comparison with the case of using no additional gas because etching rates of SiO₂ layers were increased, and as a result, sufficient residual thicknesses of the photoresists could be obtained. Further, as a comparative example, the same plasma etching was performed by replacing the C₆F₆ gas with C₄F₆ for each of the cases of using no additional gas and using C₄F₈ as an additional gas. When no additional gas was used, a residual thickness of the photoresist and an etching time were measured to be 93 nm and 190 seconds, respectively. In contrast, when C₄F₈ was used as the additional gas, the residual thickness of the photoresist becomes zero during the plasma etching, so that an overetching could not be performed.

In accordance with the embodiment of the present invention as described above, a selectivity of a silicon-containing dielectric layer against an organic photoresist layer can be greatly improved in comparison with conventional cases during a plasma etching performed in the course of manufacturing semiconductor devices. Here, it is to be noted that the present invention is not limited to the embodiment as described above but can be modified in various ways. For example, the plasma etching apparatus is not limited to the parallel plate type plasma etching apparatus as shown in FIG. 2 in which high frequency powers are applied to the upper and the lower electrode, respectively; but, instead, a plasma etching apparatus of a type in which tow different high frequency powers are applied to a lower electrode can be employed, or any of other various types of plasma etching apparatuses can be utilized.

While the invention has been shown and described with respect to the embodiment, it will be understood by those skilled in the art that various changes and modifications may be made without departing from the scope of the invention as defined in the following claims.

What is claimed is:

1. A plasma etching method comprising the step of:
performing a plasma etching on a silicon-containing dielectric layer formed on a substrate to be processed by using a plasma, while using an organic layer as a mask,
wherein the plasma is generated from a processing gas at least including a C₆F₆ gas, a rare gas and an oxygen gas, and a flow rate ratio of the oxygen gas to the C₆F₆ gas (an oxygen gas flow rate/a C₆F₆ gas flow rate) is set to be about 2.8 to 3.3.

2. The plasma etching method of claim 1, wherein the organic layer is a photoresist layer, and the silicon-containing dielectric layer is a silicon oxide layer.

3. The plasma etching method of claim 1, wherein the rare gas is an argon gas.

4. The plasma etching method of claim 1, wherein the processing gas further includes an additional gas made up of a fluorocarbon gas having a fluorine/carbon (F/C) atom ratio equal to or larger than 2.

5. The plasma etching method of claim 4, wherein the additional gas is CF₄, C₂F₆, C₃F₈, C₄F₈, C₅F₁₂, or C₆F₁₄.

6. The plasma etching method of claim 1, wherein the plasma etching is performed, in a processing chamber having a lower electrode for mounting the substrate to be processed thereon and an upper electrode disposed to face the lower electrode, by applying high frequency powers between the upper and the lower electrode.

7. The plasma etching method of claim 6, wherein the high frequency powers include a first high frequency power applied to the upper electrode; and a second high frequency power applied to the lower electrode, wherein a frequency of the second high frequency power is lower than that of the first high frequency power.

8. A plasma etching apparatus comprising:
a processing chamber for accommodating therein a substrate to be processed;
a control unit for performing the plasma etching method of claim 1 in the processing chamber;
a processing gas supply unit for supplying the processing gas into the processing chamber; and
a plasma generating unit for converting the processing gas supplied from the processing gas supply unit into a plasma, thereby plasma-etching the substrate.

9. A computer-executable control program, which controls, when executed, a plasma etching apparatus to perform the plasma etching method of claim 1.

10. A computer-readable storage medium for storing therein a computer executable control program, wherein the control program, when executed, controls a plasma etching apparatus to perform the plasma etching method of claim 1.
